(19) United States
(12) Patent Application Publication
(10) Pub. No.: US 2011/0109828 A1
(43) Pub. Date: May 12, 2011

(54) RECESSED CHANNEL TRANSISTOR DEVICES, DISPLAY APPARATUSES INCLUDING RECESSED CHANNEL TRANSISTOR DEVICES, AND METHODS OF FABRICATING RECESSED CHANNEL TRANSISTOR DEVICES

(76) Inventors: Young-mok Kim, Yongin-si (KR); Yong-sang Jeong, Suwon-si (KR); Tae-cheol Lee, Yongin-si (KR)

(21) Appl. No.: 12/797,672

(22) Filed: Jun. 10, 2010

(30) Foreign Application Priority Data
Nov. 12, 2009 (KR) 10-2009-0109175

(51) Int. Cl. G02F 1/1368; H01L 29/78; H01L 21/336

(52) U.S. Cl. 349/46; 257/330; 438/270; 257/E29.262; 257/E21.41

(57) ABSTRACT

Recessed channel transistor (RCT) devices, methods of manufacturing the RCT devices, and a display apparatuses including the RCT devices. A RCT device includes a substrate, a first trench in the substrate and having a first width; a first gate insulating layer on an inner wall of the first trench; a first recess gate on the first gate insulating layer and having a groove in a center portion of an upper surface of the first recess gate; and a source and drain in the substrate on both sides of the first recess gate.

### CROSS-REFERENCE TO RELATED APPLICATION

This application claims priority under 35 U.S.C. §119 to Korean Patent Application No. 10-2009-0109175, filled on Nov. 12, 2009, in the Korean Intellectual Property Office (KIPO), the entire contents of which is incorporated herein by reference.

### BACKGROUND

1. Field

Example embodiments of the inventive concepts relate to semiconductor devices, and more particularly, to recessed channel transistor (RCT) devices having a recess gate structure, methods of manufacturing the RCT devices, and display apparatuses including the RCT devices.

2. Description of the Related Art

As the degree of semiconductor device integration increases the pattern pitch of semiconductor devices may rapidly decrease. In particular, as transistor size is reduced the transistor channel length may be reduced and a short channel effect may be present. Accordingly, to reduce transistor size without reducing channel length, a transistor having a recess channel structure (RCT) has been introduced.

In a RCT, a gate insulating layer may be disposed between gate polysilicon (GPOLY) forming a gate electrode and a source/drain region. An undesired gate induced drain leakage (GIDL) current may be generated when a high electric field is applied to the drain. In order to overcome this problem, the thickness of the gate insulating layer may be increased and/or the density of the source/drain may be lowered. However, in this case, the manufacturing process of the RCT may be complicated and/or a current driving capability of the device may be degraded.

GIDL current may be more frequently generated in a display driver IC (DDI) to which a high voltage may be applied and which may include a RCT having a relatively wide recess gate.

### SUMMARY

Example embodiments of the inventive concepts provide recessed channel transistor (RCT) devices in which a gate induced drain leakage (GIDL) current is reduced and/or prevented, methods of manufacturing the RCT devices, and a display apparatuses including the RCT devices.

According to example embodiments of the inventive concepts, there is provided a recessed channel transistor (RCT) device that may include a substrate, a first trench that is formed in the substrate and has a first width, a first gate insulating layer formed on an inner wall of the first trench, a first recess gate that is formed on the first gate insulating layer and has a groove in a center portion of an upper surface of the first recess gate, and a source and a drain formed in the substrate on both sides of the first recess gate.

The RCT device may further include a second trench that has a width so large that an inner portion of the second trench is completely filled by a silicon gap-fill process, and the polysilicon layer may be formed at a height so as not to overlap the source and the drain in a horizontal direction. In detail, the source and the drain may include a highly doped high-density doping region in an upper portion and a lowly doped low-density doping region in a lower portion, and the polysilicon layer may be formed at a height so as not to overlap with the high-density doping region in a horizontal direction.

According to example embodiments of the inventive concepts, there is provided a recessed channel transistor (RCT) device that may include a substrate including a first trench, a gate insulating layer on the substrate in the first trench, a gate on the gate insulating layer, a groove in a surface of the gate, and a source and drain in the substrate adjacent to the gate.

According to example embodiments of the inventive concepts, there is provided a display apparatus that may include a liquid crystal display panel including a plurality of gate lines and a plurality of data lines, a gate driver for driving the plurality of gate lines, a source driver for driving the plurality of data lines, and a memory for storing digital video data and supplying the digital video data to the source driver. A transistor included in the gate driver or the source driver may be formed of the above-described RCT device. The RCT device may also be formed in the memory.

According to example embodiments of the inventive concepts, there is provided a method of manufacturing a recessed channel transistor (RCT) device. The method may include forming a trench having a width so large that an inner portion of the trench is not completely filled using a polysilicon gap-fill process, on a substrate, forming a gate insulating layer on an inner wall of the trench and on an upper surface of the substrate, forming a polysilicon layer that covers the trench, on the gate insulating layer, by using a polysilicon gap-fill process, forming a photoresist (PR) on the polysilicon layer so as to fill an unfilled portion of the trench, forming a recess gate by removing the PR and the polysilicon layer by using an etch-back process while maintaining the polysilicon layer in a lower portion of the trench, and forming a source or drain on the substrate on both sides of the trench.

In the removing the photoresist and the polysilicon layer, when the PR remains, the remaining PR may be removed by using a PR strip process. Accordingly, a groove may be formed in a center portion on an upper surface of the recess gate by removing the remaining PR. The forming of the PR may include coating the PR while adjusting a coating recipe of the PR and reflowing the PR. In the forming of the PR, the PR may be spin-coated while adjusting a coating recipe of the PR, and the adjusting of a coating recipe of the PR may comprise adjusting a spin coating speed of the PR and adjusting viscosity of the PR.

According to example embodiments of the inventive concepts, there is provided a method of manufacturing a recessed channel transistor (RCT) device. The method may include forming a first trench on a substrate, forming a gate insulating layer on an inner surface of the first trench, forming a gate layer on the gate insulating layer in the first trench, the gate layer formed such that the first trench includes an unfilled inner portion, forming a recess gate by removing a part of the gate layer from the first trench, and forming a source and a drain adjacent to the first trench.

### BRIEF DESCRIPTION OF THE DRAWINGS

Example embodiments of the inventive concepts will be more clearly understood from the following brief description taken in conjunction with the accompanying drawings. FIGS. 1-4H represent non-limiting, example embodiments as described herein.

FIG. 1 is a cross-sectional diagram illustrating a recessed channel transistor (RCT) device according to example embodiments of the inventive concepts;

FIG. 2 is a cross-sectional diagram illustrating a RCT device according to example embodiments of the inventive concepts;

FIG. 3 is a block diagram illustrating a display apparatus including a RCT device according to example embodiments of the inventive concepts; and

FIGS. 4A-4H are cross-sectional diagrams illustrating methods of manufacturing the RCT device of FIG. 2 according to example embodiments of the inventive concepts.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments of the inventive concepts to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments of the inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments of the inventive concepts. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments of the inventive concepts.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

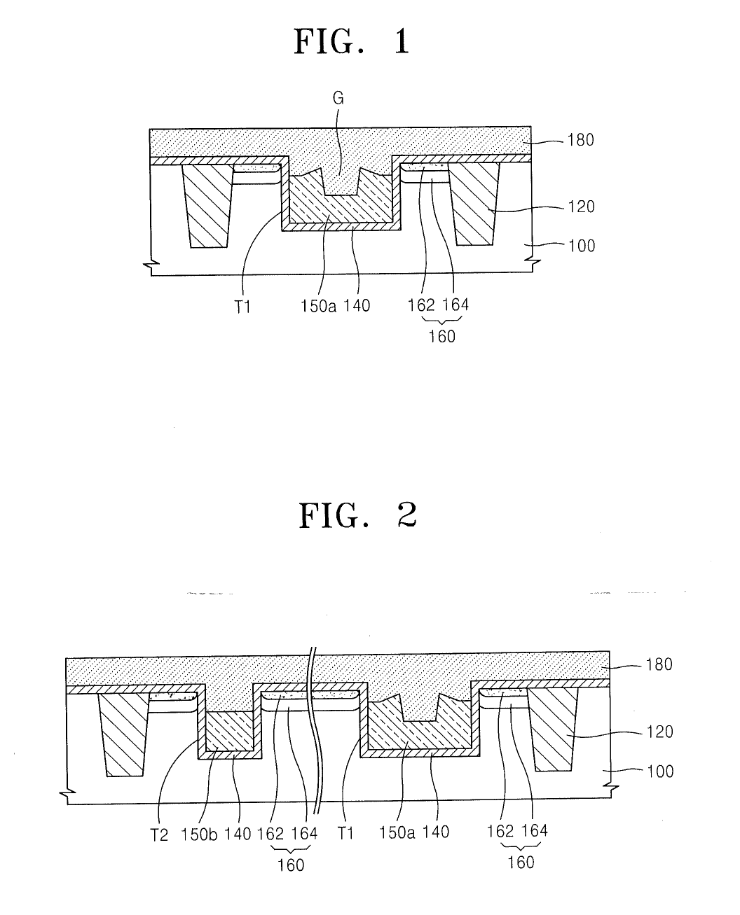

FIG. 1 is a cross-sectional diagram illustrating a recessed channel transistor (RCT) device according to example embodiments of the inventive concepts. Referring to FIG. 1, a RCT device may include device isolation layers 120 in a substrate 100, a recess gate 150a between the device isolations layers 120, a gate insulating layer 140 partially surrounding the recess gate 150b, and a source/drain 160 on both sides of the recess gate 150a. The substrate 100 may be, for example, a semiconducting layer (e.g., a bulk semiconductor substrate, a semiconductor-on-insulator substrate, and/or an epitaxial layer). The gate insulating layer 140 may be between the recess gate 150a and the source/drain 160. The source/drain 160 may include a high-density doping region 162 and/or a low-density doping region 164. The high-density doping region 162 may be heavily doped in comparison to the low-density doping region 164. An interlayer dielectric layer (ILD) 180 may be on the recess gate 150a and the gate insulating layer 140. A capping insulating layer (not shown) may be on the upper surface of the recess 150a between the recess gate 150a and the interlayer insulating layer. A contact plug (not shown) may penetrate through the ILD 180 and the gate insulating layer 140 and may be electrically connected to the source/drain 160.

The recess gate 150a may be formed by forming a trench T1 in the substrate 100 and by filling a gap of the trench T1 with polysilicon. According to example embodiments, the trench T1 may have a width large enough so that the trench T1 may not be completely filled by a polysilicon gap-fill process. Accordingly, after polysilicon gap-filling, a portion of a center of the trench T1 may not be completely filled and may remain hollow.

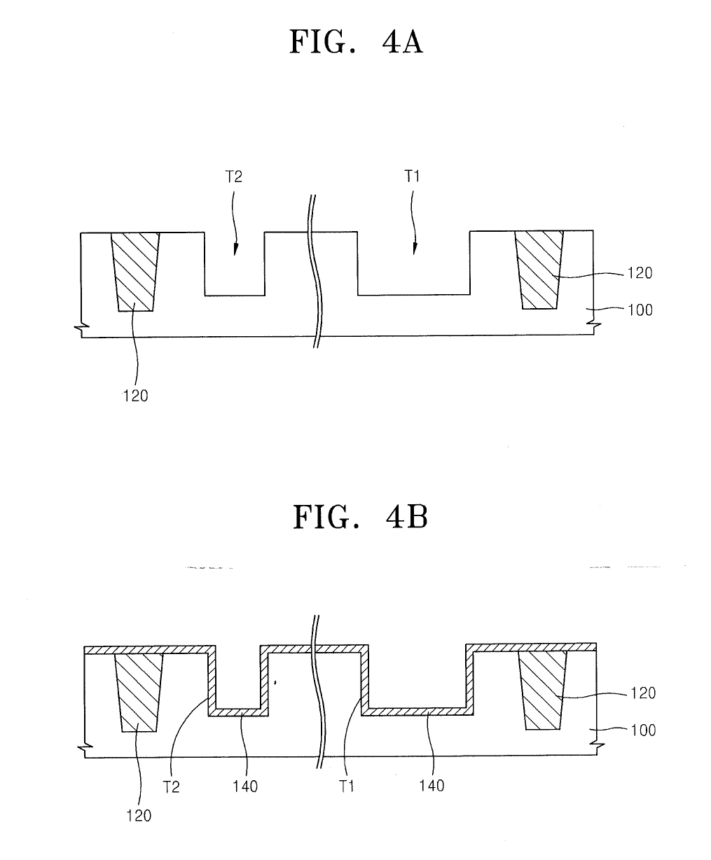

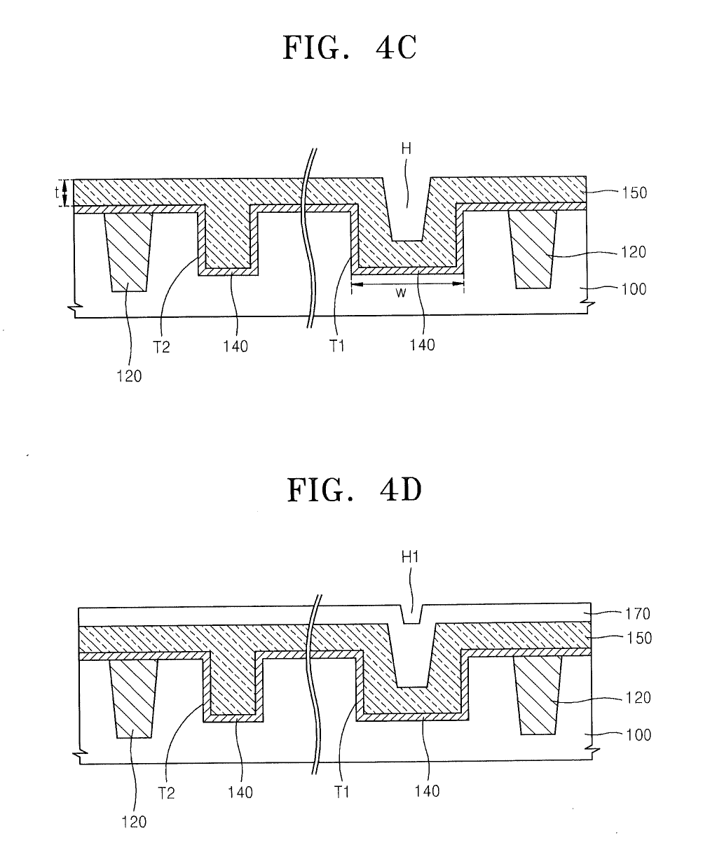

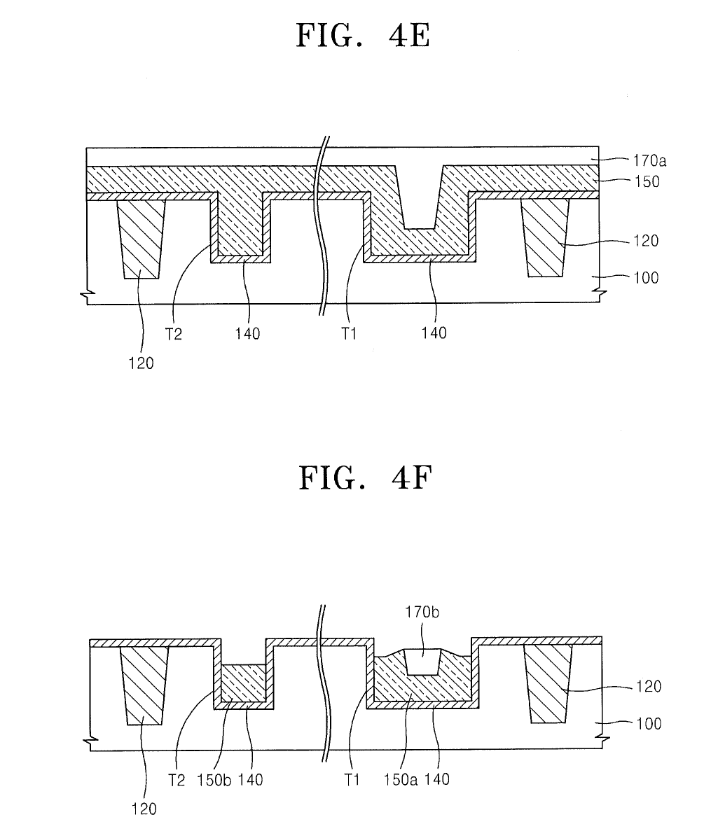

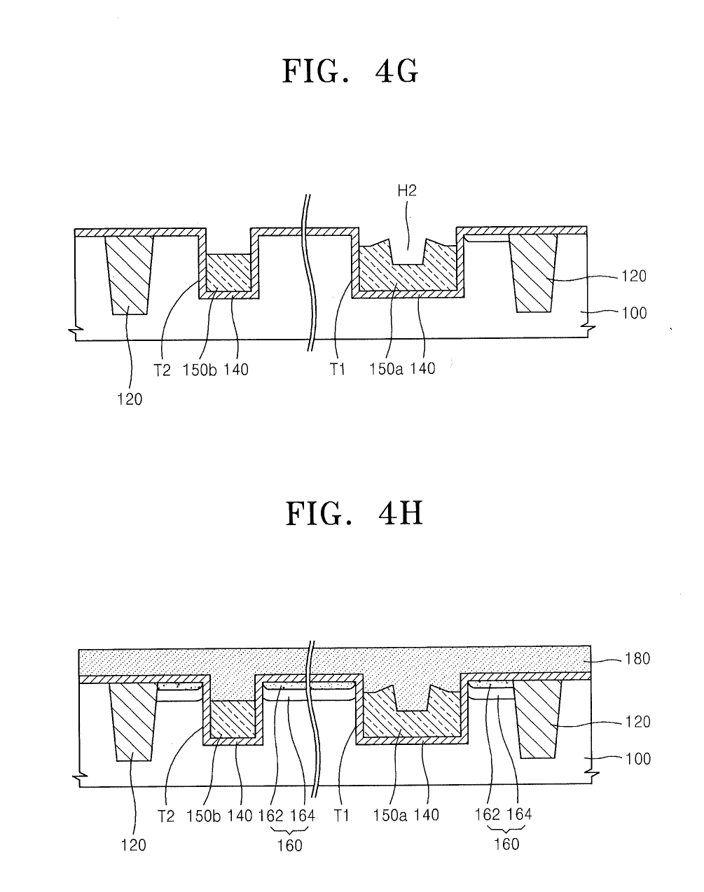

When the trench T1 is filled by polysilicon gap-filling, the polysilicon may be conformal to an inner wall of the trench T1. The width of the trench T1 may be large enough so that the trench T1 is not completely filled by the polysilicon gap-fill process. The width of the trench T1 may be determined by a width w of the trench T1 and a thickness t of the polysilicon. For example, when the width w of the trench T1 is more than twice the thickness t of the polysilicon, the trench T1 may not be completely filled by the polysilicon gap-filing (see FIG. 4C). When a portion of the trench T1 is not filled, an etch-back process for removing polysilicon may not be performed because polysilicon may not remain in a portion of the trench after etch-back. The center of the trench T1 where a thickness of polysilicon is small may be exposed when an etch-back process is performed. When the trench T1 is not completely filled an etch-back process may not be performed.

According to example embodiments, after a polysilicon gap-fill process is performed on a substrate, a photoresist (PR) may be coated thereon and a PR reflow process may be performed. An empty portion of the trench T1 may be filled with PR using the PR reflow process. An etch-back process may be performed to remove polysilicon in an upper portion of the trench T1. If PR is left in the trench T1 after the etch-back process, the PR may be removed by using a PR strip process. The same effect obtained by the PR reflow process may also be obtained by adjusting a coating recipe in a PR spin coating process, for example, by adjusting a spin coating speed or PR viscosity. The same effect may also be obtained by both using a PR reflow process and adjusting a PR coating recipe; the empty portion of the trench T1 may be filled with PR. A groove G may be formed in polysilicon remaining in the trench T1 in an upper surface of the recess gate 150a after the etch-back process. The upper surface of the recess gate 150a may be maintained at a height so that the recess gate 150a does not overlap the source/drain 160 adjacent thereto in a horizontal direction. A top surface of the recess gate 150a may be at a lower level than a top surface of the substrate 100.

The upper surface of the recess gate 150a may be lower than a lower surface of the source/drain 160. When the source/drain 160 includes a high-density doping region 162 and a low-density doping region 164, the upper surface of the recess gate 150a may be maintained at a height so that the recess gate 150a does not overlap the high-density doping region 162. The upper surface of the recess gate 150a may overlap the low-density doping region 164.

Because the upper surface of the recess gate 150a may not overlap the high-density doping region 162 of the source/drain 160, the GIDL current, which may be generated due to a thin gate insulating layer according to the conventional art, may be reduced and/or prevented. There may not be a need to form a thick gate insulating layer in a portion where a recess gate and a source/drain overlap each other in order to prevent a GIDL current and the thickness of the gate insulating layer may be uniform on an inner surface of a trench.

In a RCT device according to the conventional art, a gate insulating layer may be between polysilicon of a gate electrode (e.g., GPOLY) and a source/drain. A GIDL current may be generated when a high electric field is applied to the drain. In order to reduce and/or prevent the GIDL current, a thickness of the gate insulating layer may be increased and/or a source/drain density may be lowered. The manufacturing process of the conventional RCT device may be complicated and/or a current driving capability of the RCT device may be degraded. The problem of the GIDL current may be more frequently generated in a DDI to which a high voltage may be applied and which may include a RCT having a relatively wide recess gate. According to the RCT device of example embodiments of the inventive concepts, because the upper surface of the recess gate 150a may not overlap the high-density doping region 162 of the source/drain 160, the GIDL current in the RCT device may be reduced and/or prevented.

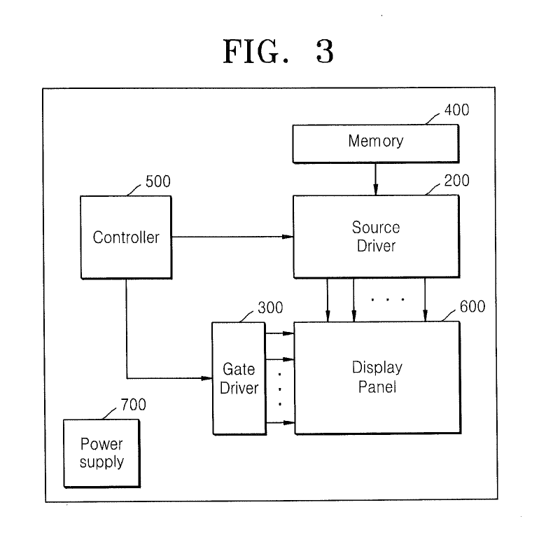

FIG. 2 is a cross-sectional diagram illustrating a RCT device according to example embodiments of the inventive concepts. Referring to FIG. 2, the RCT device of FIG. 2 is similar to the RCT device of FIG. 1 but differs therefrom in that a recess gate 150b may be further included. A width of the recess gate 150b may be smaller than the width of the recess gate 150a.

A plurality of RCT devices including recess gates may be on a substrate 100. A recess gate may be classified as one of two types of recess gates. A first type of recess gate may be a recess gate 150a in a trench T1 having a width that may not be completely filled by a polysilicon gap-fill process. A second type of recess gate may be a recess gate 150b in a trench T2 having a width that can be completely filled by polysilicon gap-fill process.

When a width of a trench is 0.6 μm or greater, it may be difficult to completely fill a trench by using a gap-fill process. In order to completely fill the trench, an additional photo mask process may be required. The width of the trench may be described as 0.6 μm to distinguish the types of recess gates, but a description is not limited thereto. According to example embodiments, a recess gate may be classified according to whether or not a trench is completely filled by a gap-fill process.

When a trench is buried by a polysilicon gap-fill process, the polysilicon may be conformal to an inner wall of the trench. In order to determine a width of the trench that is large enough so that the trench may not be completely filled with polysilicon, a width w of the trench and a thickness t of the polysilicon may be compared. For example, when the width w of the trench is more than twice the thickness t of the polysilicon, the trench may not be completely filled with the polysilicon (see FIG. 4C).

When only the narrow recess gate 150b is formed, the narrow trench T2 may be filled with polysilicon using a gap-fill process. The narrow recess gate 150b may be formed by removing polysilicon in the narrow trench T2 by using an etch-back process without using, for example, a PR reflow process. When the wide recess gate 150a is also formed according to example embodiments, a PR reflow process may be used to fill an unfilled portion of the wide trench T1 with PR. The polysilicon in the trench T1 and T2 may be removed by using an etch-back process.

An upper surface of the narrow recess gate 150b may be maintained at a height so that the narrow recess gate 150b does not overlap the source/drain 160 in a horizontal direction (e.g., a top surface of the narrow recess gate 150b may be below a bottom region of the source/drain 160). When the source/drain 160 includes a high-density doping region 162 and a low-density doping region 164, the upper surface of the narrow recess gate 150b may be formed at a height where the narrow recess gate 150b does not overlap with the high-density doping region 164 in a horizontal direction.

The wide recess gate 150a may constitute a driver transistor included in a source driver and/or a gate driver in a DDI, and/or a transistor in a logic circuit. A high voltage may be applied to the driver transistor; for example, a voltage of about 8-20 V may be applied to the driver transistor. According to example embodiments, the recess gate 150a does not overlap the source/drain 160 having a high-density and a GIDL current may be reduced and/or prevented. The narrow recess gate 150b may be applied, for example, to a transistor formed in a memory cell area. The narrow recess gate 150b may not overlap the high-density source/drain 160 having a high-density in a horizontal direction. A GIDL current in the memory cell area may be reduced and/or prevented.

While driver transistors and/or cell area transistors are described as elements to which a wide recess gate and a narrow recess gate may be applied, the wide recess gate and the narrow recess gate may also be applied to other types of transistors. With regards to a semiconductor device including both a wide recess gate and a narrow recess gate, a PR reflow process and an etch-back process may be performed to form the recess gate such that the recess gate does not overlap with a source/drain in a horizontal direction, thereby reducing and/or preventing a GIDL current.

FIG. 3 is a block diagram illustrating a display apparatus including a RCT device according to example embodiments of the inventive concepts. Referring to FIG. 3, a display apparatus may include a source driver 200, a gate driver 300, a memory 400, a controller 500, a display panel 600 and a power supply 700. The source driver 200 may receive a control signal from the controller 500 to respond to a horizontal synchronization signal HSYNC and output data line by line to the display panel 600. The gate driver 300 may receive a control signal from the controller 500 to control gate lines and sequentially output the data output by the source driver 200 to the display panel 600.

The display panel 600 may include a plurality of gate lines and a plurality of data lines to display the data input from the source driver 200. The memory 400 may store data (e.g., digital video data) and may supply the data to the source driver 200. The power supply 700 may supply power to the source driver 200, the gate driver 300, the memory 400, the controller 500 and the display panel 600. The controller 500 may receive a vertical synchronization signal VSYNC, a horizontal synchronization signal HSYNC, a data enable signal DE, and/or a clock signal CLK, and may transmit control signals to the source driver 200 and the gate driver 300. If the memory 400 is not connected to the source driver 200 but is directly connected to the controller 500, the controller 500 may transmit the data to the source driver 200.

According to example embodiments of the inventive concepts, the source driver 200 and the gate driver 300 may include a plurality of driver transistors, respectively, and the driver transistors may include wide recess gates. The driver transistors may have wide recess gates that do not overlap with high-density source/drain regions in a horizontal direction by using a PR reflow process and an etch-back process, thereby reducing and/or preventing a GIDL current. A plurality of transistors may be included in the memory 400 and the transistors may include narrow recess gates. The narrow recess gates may be formed by using a PR reflow process and an etch-back process so as not to overlap with high-density source/drains in a horizontal direction. A GIDL current in the cell areas may also be reduced and/or prevented.

The display apparatus may include RCTs according to example embodiments of the inventive concepts, for example, as described with reference to FIGS. 1 and 2. A RCT device according to example embodiments of the inventive concepts may be applied, for example, to a source driver and/or a gate driver of a display apparatus, and also to any other device that may include a transistor having a wide recess gate. For example, other logic device elements and/or electronics and/or electric devices.

FIGS. 4A-4H are cross-sectional diagrams illustrating methods of manufacturing the RCT device of FIG. 2 according to example embodiments of the inventive concepts. Referring to FIG. 4A, trenches T1 and T2 may be formed in a substrate 100 in which a plurality of device isolation layers 120 that define an active region may be formed. The trench T1 on the right side in FIG. 4A may be for forming a wide recess gate and the trench T2 on the left side in FIG. 4A may be for forming a narrow recess gate. The trench T1 may be wide enough so that the trench T1 may not be completely filled during a polysilicon gap-fill process. The trench T2 may be narrow enough so that the trench T2 may be filled by using a polysilicon gap-fill process.

Referring to FIG. 4B, a gate insulating layer 140 may be formed on the substrate 100 in which the trenches T1 and T2 are formed. The gate insulating layer 140 may also formed on inner walls of the trenches T1 and T2. The gate insulating layer 140 may be formed of, for example, a silicon oxide layer and/or a high-k dielectric material. Referring to FIG. 4C, a polysilicon layer 150 may be formed on the gate insulating layer 140. The trenches T1 and T2 may be filled and/or partially filled with polysilicon. This filling of the trenches T1 and T2 with polysilicon may be referred to as a polysilicon gap-fill process. As illustrated in FIG. 4C, the trench T2 on the left side may be completely filled with polysilicon. The trench T1 on the right side may not be completely filled with polysilicon and a hollow center portion H may be present therein. A width w of the trench T1 may be twice or more than twice a thickness t of the polysilicon layer 150. Because the center portion H is hollow, an etch-back process may not be performed to remove the polysilicon in the trench T1.

Referring to FIG. 4D, a PR layer 170 may be coated on the polysilicon layer 150. A PR layer may be formed to a desired thickness by adjusting a PR coating recipe. According to example embodiments, the PR layer 170 may be formed on the substrate 100 with a uniform thickness. A groove H1 may be formed in a portion of the trench T1 that is not filled with polysilicon, as illustrated in FIG. 4D. A ratio of etch selectivities of the PR layer 170 and the polysilicon layer 150 may be about 1:0.5-2 so that the PR layer 170 and polysilicon layer 150 are removed at a similar etch speed in a subsequent etch-back process.

Referring to FIG. 4E, a PR reflow process may be performed to remove the groove H1 formed in the trench T1 after coating the PR layer 170. The PR reflow process may refer to an operation in which a PR layer 170a is formed by heating the PR layer 170 (e.g., to a temperature of about 100° C.) so that a PR flows into the groove H1 (e.g., to fill the groove H1). As illustrated in FIG. 4E, the groove H1 of the trench T1 may be removed. Alternatively, the groove H1 may not be formed by, for example, adjusting a PR coating recipe before the PR reflow process. For example, by adjusting a speed of spin coating and/or viscosity of a PR, the PR may flow into the groove H1, thereby removing the groove H1. When the groove H1 is removed by adjusting a PR coating recipe, the PR reflow process may be omitted. In order to remove the groove H1, both adjustment of the PR coating recipe and the PR reflow process may be performed.

According to example embodiments, the groove H1 of the trench T1 may be filled by adjusting a PR coating recipe, performing a PR reflow process, and/or by adjusting both a PR coating recipe and a PR reflow process. A PR mask process may not be performed to fill an unfilled portion of the trench T1.

Referring to FIG. 4F, an etch-back process may be performed on the substrate 100. Most of the polysilicon and the PR on the gate insulating layer 140 may be removed by using the etch-back process. The polysilicon and PR 170b may remain in lower portions of the trenches T1 and T2. The polysilicon remaining in the lower portions of the trenches T1 and T2 may be recess gates 150a and 150b, respectively. An upper surface of the polysilicon that remains after the etch-back process (e.g., recess gates 150a and 150b) may be maintained at a height where the recess gates 150a and 150b do not overlap source/drain regions 160 which may be formed on both sides of the recess gates 150a and 150b, respectively. The upper surfaces of the recess gates 150a and 150b may be lower than a lower surface of the source/drain region. The upper surfaces of the recess gates 150a and 150b may be lower than a lower surface of a high-density doping region of the source/drain region. According to the conditions of the etch-back process, the upper surfaces of the recess gates 150a and 150b may be planarized (not shown).

Referring to FIG. 4G, the PR 170b remaining in the wide recess gate 150a may be removed by using a PR strip process. A groove H2 may be formed in a center portion of the wide recess gate 150a. The recess gate 150a may have varying depths with respect to a top surface of the substrate 100. If no PR remains in the wide recess gate 150a the PR strip process may be omitted. Referring to FIG. 4H, both side portions of the recess gates 150a and 150b may be doped with impurities to form source/drain regions 160. A source/drain 160 may include a high-density doping region 162 in an upper portion and a low-density doping region 164 in a lower portion by adjusting a doping density. According to example embodiments, the upper surfaces of the recess gates 150a and 150b may be lower than a lower surface of the high-density doping region 162 so that the recess gates 150a and 150b do not overlap the high-density doping region 162 in a horizontal direction.

An ILD 180 may be formed on the substrate 100. A capping insulating layer (not shown) may be formed on the upper surfaces of the recess gates 150a and 150b in the trenches T1 and T2 and the ILD 180 may be formed on the capping insulating layer. Subsequent processes may be the same as those in a typical RCT manufacturing process, and thus description thereof will be omitted.

While example embodiments of the inventive concepts have been particularly shown and described, it will be understood by one of ordinary skill in the art that variations in form and detail may be made therein without departing from the spirit and scope of the claims.

What is claimed is:

1. A recessed channel transistor (RCT) device comprising:
a substrate including a first trench;
a gate insulating layer on the substrate in the first trench;
a gate on the gate insulating layer, a groove in a surface of the gate; and
a source and drain in the substrate adjacent to the gate.

2. The RCT device of claim 1, further comprising:
a second trench on a surface of the substrate; and
a second gate in the second trench,
wherein the gate and the second gate include a gate layer,
the gate layer is at least substantially conformal to the first and second trenches,
the groove is in the first trench between opposing surface regions of the gate layer on sidewalls of the first trench, and
at least a portion of opposing surface regions of the gate layer on sidewalls of the second trench are in contact.

3. The RCT device of claim 1, wherein the gate includes a gate layer, and
a width of the first trench is greater than about twice a width of the gate layer.

4. The RCT device of claim 1, wherein the gate does not substantially overlap at least one of the source and drain.

5. The RCT device of claim 1, wherein at least one of the source and drain includes a high-density doping region and a low-density doping region, and
the gate does not overlap the high-density doping region and overlaps the low-density doping region.

6. The RCT device of claim 1, wherein the first gate insulating layer is about a uniform thickness in the first trench.

7. The RCT device of claim 1, further comprising:
an interlayer dielectric (ILD) layer on the gate.

8. A display apparatus comprising the RCT of claim 1.

9. The display apparatus of claim 8, further comprising:
a liquid crystal display panel including a plurality of gate lines and a plurality of data lines;
a gate driver configured to drive the plurality of gate lines;
a source driver configured to drive the plurality of data lines, at least one of the source driver and the gate driver including the RCT device; and
a memory configured to store data,
wherein the gate does not substantially overlap at least one of the source and drain.

10. A method of manufacturing a recessed channel transistor (RCT) device, the method comprising:
forming a first trench on a substrate;
forming a gate insulating layer on an inner surface of the first trench;
forming a gate layer on the gate insulating layer in the first trench, the gate layer formed such that the first trench includes an unfilled inner portion;
forming a recess gate by removing a part of the gate layer from the first trench, the recess gate formed such that a top surface of the recess gate is at a lower level than a top surface of the substrate; and
forming a source and a drain adjacent to the first trench.

11. The method of claim 10, further comprising:
forming a photoresist (PR) layer on the gate layer to fill the unfilled inner portion of the first trench.

12. The method of claim 11, wherein at least a portion of the PR layer remains after the removing of the part of the gate layer from the first trench,
the forming of the recess gate includes removing the part of the gate layer from the first trench using an etch-back process and stripping the remaining portion of the PR layer by using a PR strip process, and
the forming of the gate layer includes forming the gate layer using a gap fill process.

13. The method of claim 12, wherein a groove is formed in a center portion on an upper surface of the recess gate by the stripping of the remaining portion of the PR layer.

14. The method of claim 11, wherein the forming of the PR layer includes reflowing a PR.

15. The method of claim 14, wherein the forming of the PR layer includes spin-coating the PR according to a coating recipe such that the PR at least substantially fills the unfilled inner portion of the first trench, and
the coating recipe specifies a spin coating speed and a viscosity of the PR.

16. The method of claim 10, further comprising:
forming a second trench on the substrate,
wherein the forming of the gate layer includes forming the gate layer in the second trench such that an inner portion of the second trench is filled by a material of the gate layer.

17. The method of claim 10, wherein
the recess gate layer does not substantially overlap at least one of the source and drain.

18. The method of claim 10, wherein at least one of the source and drain includes a high-density doping region and a low density doping region, and
the recess gate does not overlap the high-density doping region and overlaps the low-density doping region.

19. The method of claim 12, wherein an etch selectivity ratio of the PR layer and the gate layer is about 1:0.5-2.

20. The method of claim 10, further comprising:
forming an interlayer dielectric (ILD) layer on the substrate and the recess gate.
